(19) United States
(12) Patent Application Publication
(10) Pub. No.: US 2026/0049404 A1
(43) Pub. Date: Feb. 19, 2026

(54) PHOTOELECTRIC CELL WITH SILICON CARBIDE ELECTRODE AND PRODUCTION METHOD FOR SAME

(71) Applicant: The Yellow SiC Holding GmbH, Berlin (DE)

(72) Inventor: Siegmund GREULICH-WEBER, Berlin (DE)

(73) Assignee: The Yellow SiC Holding GmbH, Berlin (DE)

(21) Appl. No.: 19/101,610

(22) PCT Filed: Aug. 24, 2023
(86) PCT No.: PCT/EP2023/073220

§ 371 Date: Feb. 6, 2025

(30) Foreign Application Priority Data
Aug. 30, 2022 (DE) 10 2022 121 924.0

(51) Int. Cl. C25B 9/50; C23C 16/32; C25B 9/19; C25B 11/031; C25B 11/052; C25B 11/061; C25B 11/087

(52) U.S. Cl. CPC C25B 9/50; C23C 16/325; C25B 9/19; C25B 11/031; C25B 11/052; C25B 11/061; C25B 11/087

(57) ABSTRACT

Disclosed are a photoelectric cell with a silicon carbide electrode (4) for photocatalytic production of hydrogen, and a manufacturing method therefor. The cell has on one side of the silicon carbide electrode (4) a window (2) the incidence of light (5) and on the other side of the silicon carbide electrode (4) an aqueous electrolyte (10) and a counter electrode (6). On the side of the silicon carbide electrode (4) facing the window, the cell is electrolyte-free. The silicon carbide electrode (4) is preferably produced by coating a substrate (3) with silicon carbide (4).

The invention relates to a photoelectric cell with a silicon carbide electrode for the photocatalytic production of hydrogen, and a manufacturing method therefor.

Work on the provision of hydrogen as an energy source has been going on for a long time, but no breakthrough has yet been achieved for widespread use.

EP 3268512 B1 discloses a photoelectric cell for the production of hydrogen by electrolytic splitting of water when irradiated with sunlight (photocatalysis). The cell contains a SiC electrode in which the sunlight generates charge carriers and an electric current which causes the electrolytic splitting of the water. The SiC electrode has a porous fiber structure. This structure is intended to provide a large surface area and is produced by trans-forming carbon fibers into silicon carbide in a method according to EP 2094622 B1, for example.

Both EP 3268512 B1 and other known structures have the disadvantage that the sunlight must first pass through a glass plate several millimetres thick and then through a layer of water before it reaches the active SiC material. Glass and water absorb significant portions of the solar spectrum, which are then no longer available for photocatalysis. Photocatalysis for the splitting of water can be operated with photon energies from just over 2 eV, while conventional glass absorbs sunlight noticeably from around 3.5 eV upwards. The usable part of the sunlight spectrum is therefore limited to about the 2 to 3.5 eV range. In addition, conventional glass reflects a considerable proportion of the sunlight over the entire spectral range which is lost to the photocatalysis.

Furthermore, in a known manufacturing method of the electrodes, carbon fibers are transformed into SiC only on their surface. Carbon fibers with a thickness of 10 μm, for example, only have an approximately 2-3 μm thin layer of SiC on their surface, in which only a portion of the light falling on is effectively absorbed photocatalytically. The core of the fibers is untransformed carbon and is opaque.

The part of the light absorbed there only leads to heating of the electrode and is lost to the photocatalysis. The desired increase in surface area due to the porosity of the fiber structure hardly helps here. The porosity is typically only around 50%.

Another disadvantage of the known electrodes is the fundamentally high contact resistance within the electrode due to the fiber structure, which leads to significant electrical losses.

It is, therefore, an object of the invention to provide a technology that allows the photocatalytic production of hydrogen with improved efficiency.

The solution to this problem is achieved with the photoelectric cell and the manufacturing method specified in the appended claims.

The invention uses a photo-electrode in the form of a layer of 3C-SiC or amorphous SiC. 3C-SiC (cubic silicon carbide) with a band gap of 2.36 eV is suitable for efficiently generating charge carriers of sufficient energy to electrolytically split water without the need for additional application of an electrical voltage, simply by irradiation with sunlight. The spectrum of sunlight is used efficiently. The same applies to amorphous SiC, which has a band gap of around 2.2 eV. 4H-SiC and 6H-SiC (hexagonal), on the other hand, have a band gap of 3.27 eV and 3.03 eV and therefore only absorb shorter-wavelength light and utilize the spectrum of sunlight less efficiently. The layer can be an independent plate or a coating of a substrate with SiC, for example a substrate made of metal, graphite, plastic, glass or similar provided with nano-or micro crystalline 3C-SiC or amorphous SiC. The SiC layer can be undoped, p-doped with Al or B, for example, and/or co-doped with transition metal elements such as Fe, Cr, V, for example. The photo-electrode is an electrode with a surface facing the light. This surface can be coated with a co-catalyst, such as Pt or Pd.

Embodiments of the invention achieve an improvement of the optical transmission or a reduction of the reflection on the optical path to the electrode, an increase in the optically or electrochemically active electrode surface, an improvement in the electrical conductivity and contacting of the electrode and a simple scalability of the cell size (“up-scaling”to square meter-sized modules and larger).

Embodiments of the invention are shown in the drawings which show in:

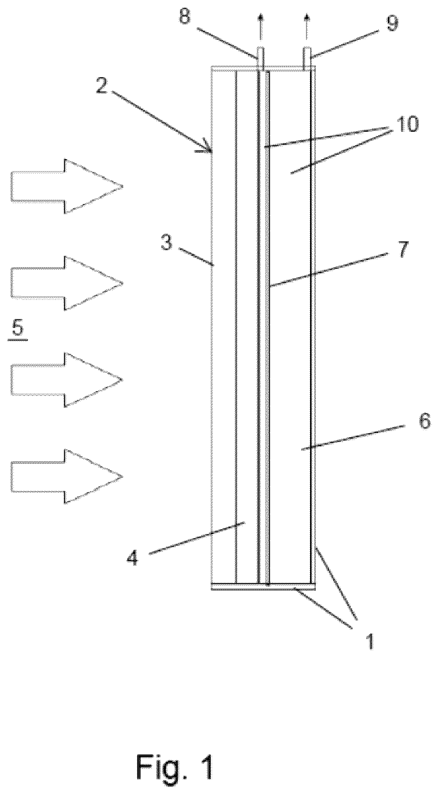

FIG. 1 a schematic representation of a photoelectric cell according to a first embodiment;

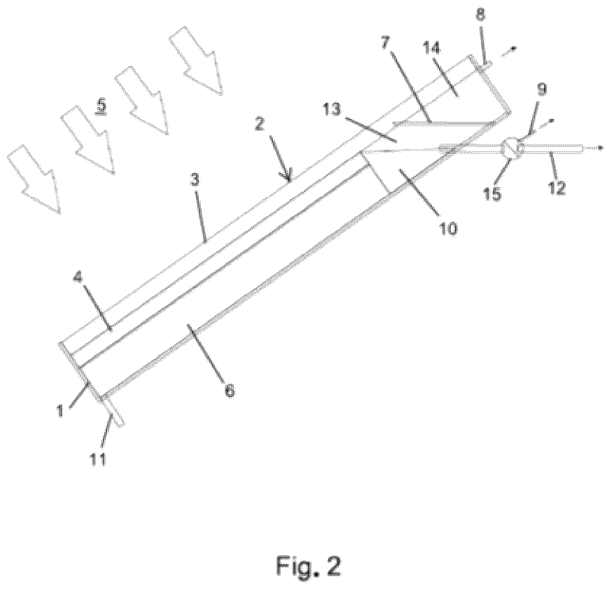

FIG. 2 a more detailed representation of a photoelectric cell according to a second embodiment derived from the first, and

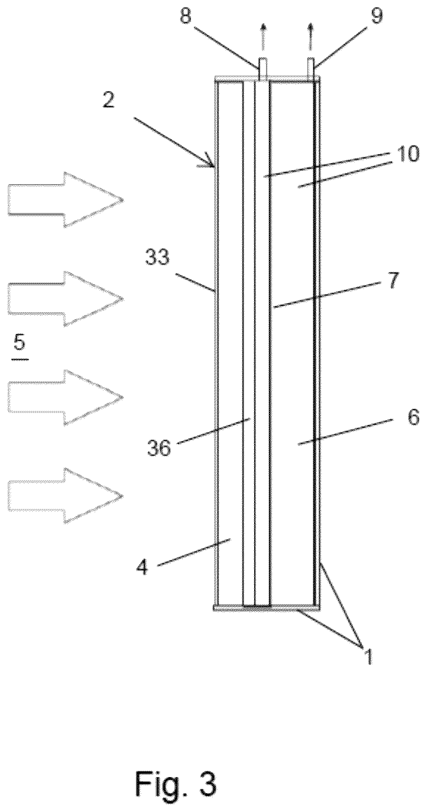

FIG. 3 a schematic representation of a photoelectric cell according to a third embodiment.

Identical elements are provided with the same reference signs in all Figures and are not described again for each Figure.

The photoelectric cell shown in FIG. 1 comprises a housing 1 with a light transmissive window 2. In the present embodiment, the window 2 is provided with a transparent plate 3, in particular a glass plate 3.

Alternatively, a transparent plastic plate can also be used.

Viewed from the direction of incident sunlight 5, an electrode 4 made of 3C silicon carbide is located directly behind the transparent plate 3 inside the housing 1. Preferably, the 3C-Sic is nano-or microcrystalline. Alternatively, amorphous SiC can also be used. This SiC electrode 4 has the form of a thin non-porous or barely porous SiC layer 4 with a thickness in the range of 40 to 80 μm. Within this thickness, sunlight 5 entering through the window 2 is absorbed as well as possible. The SiC layer 4 can be one that is applied on the transparent plate 3, which then serves as a transparent substrate 3.

On the other side of the SiC electrode 4, i.e. opposite its side where the window 2 is located, a counter electrode 6 is arranged, in this case at a distance from the Sic electrode. The counter electrode is a metal foam 6 with good electrical conductivity, in this preferred embodiment example nickel foam 6. The metal or nickel foam 6 has a thickness in the range of approximately 3 to 40 mm. The surface of the metal foam 6 can be provided with a catalyst that facilitates the splitting of water. Polyoxometalates are particularly suitable as catalysts, on the nickel foam 6 especially those made from nickel, cobalt and tungsten.

The nickel foam 6 is impregnated with an aqueous electrolyte 10, which also comes into contact with the Sic electrode 4 and in which the water contained therein is to be split into hydrogen and oxygen. The housing 1 has an inlet and an outlet (not shown in FIG. 1) for circulating the electrolyte or water, respectively, through the nickel foam 6 in the housing 1.

An electrical conductor, in this case the electrically conductive or conductively coated housing 1, closes the circuit between nickel foam 6 and SiC electrode 4. A transparent conductive layer can be provided between window 2 and SiC electrode 4, which is electrically connected to that conductor and contacts the SiC electrode 4 over a large area and with a low resistance.

The housing 1 has an outlet 8 for gaseous hydrogen and an outlet 9 for gaseous oxygen.

A proton-permeable membrane 7 (shown schematically) is provided between the SiC electrode 4 and the nickel foam 6. The membrane 7 separates the electrolyte-impregnated nickel foam 6 from the outlet 8 for hydrogen and allows hydrogen to pass to the outlet 8, but not the aqueous electrolyte 10 itself and the oxygen. The outlet 9 for gaseous oxygen is directly connected to the impregnated nickel foam 6.

The surface of the SiC electrode 4 facing the electrolyte 10 can be provided with a metal layer, for example of solid metal and/or metal or nickel foam. Such a modification of the embodiment of FIG. 1 is described further below in connection with FIG. 3.

In operation, the sunlight 5 passes through the window 2, in this case through the glass plate 3, illuminates the SiC electrode 4 and photoelectrically generates charge carriers in it, which are electrons or holes depending on the doping of the SiC electrode 4. Since the light 5 can illuminate the electrolyte-free side of the SiC electrode 4 directly without passing through the electrolyte, it is only slightly attenuated on its way to the electrode 4. With the aforementioned thickness of the SiC electrode 4 in the range of 40 to 80 μm, the penetration depth of the sunlight 5 is utilized to the maximum. Since the thin layer of the SiC electrode 4 is hardly porous or not porous at all, effective absorption of the sunlight 5 and good conductivity for the charge carriers generated therein are achieved. With the above-mentioned doping and with sufficient purity of the SiC material, a sufficient charge carrier lifetime is achieved so that the charge carriers generated in the SiC (electrons or holes, depending on the doping) can migrate to the electrolyte side of the Sic electrode 4, where the nickel foam 6 touches the Sic electrode 4, and supply the energy required for water splitting. These charge carriers are used to electrolytically generate hydrogen and oxygen from the water 10.

The membrane 7 is proton-permeable, acts as a proton separator and separates the hydrogen from the oxygen by allowing the hydrogen to diffuse to the outlet 8. The oxygen bubbles upwards out of the aqueous electrolyte 10 and exits the housing 1 through the outlet 9.

The portion of the energy of the sunlight 5 that is not absorbed in the electrolytic splitting of the water, in particular the energy content of the infrared portion of the sunlight spectrum, leads to heating of the cell. This heat energy can be dissipated from the cell by circulating the aqueous electrolyte or water, respectively, through the inlet and outlet (not shown in FIG. 1) and used for other purposes.

FIG. 2 shows in more detail a modification of the embodiment of FIG. 1. The photoelectric cell is shown here inclined so that the window 2 faces the obliquely incident solar radiation.

As in the embodiment of FIG. 1, the nickel foam 6 is impregnated with the aqueous electrolyte 10. The nickel foam is therefore in a water bath. The water level is above the nickel foam 6. FIG. 2 shows the water inlet 11 at the bottom of the housing 1 and the water outlet 12 at the top of the housing 1 at approximately the level of the water level, both of which are not shown in the more schematic FIG. 1.

In this respect, the construction and operation of the cell are similar to the embodiment of FIG. 1. However, the embodiment of FIG. 2 differs from that of FIG. 1 in the features of the membrane 7 and the outlet 9 for the oxygen, as described below.

In the embodiment of FIG. 2, the membrane 7 is arranged in a gas space 13, 14 above the water level in the housing 1, where it divides the gas space into a part 13 of higher pressure the side of the water 10 and a part 14 of lower pressure on the side of the outlet 8 for hydrogen gas. The respective pressure is maintained in operation by the production of hydrogen gas and oxygen gas in the aqueous electrolyte 10 and by the work of a compressor (not shown), which withdraws the hydrogen from the outlet 8 and feeds it to a gas network or storage. The pressure difference promotes the passage of the hydrogen through the membrane 7 and thus the separation of hydrogen and oxygen.

The outlet 9 for the oxygen gas is connected to an oxygen separator 15, which is arranged in the outlet 12 of the water, in the embodiment of FIG. 2. The circulation of the aqueous electrolyte or water 10, respectively, through the outlet 12 thus serves not only to utilize the heat of the aqueous electrolyte 10 but also to extract the oxygen from the aqueous electrolyte 10.

FIG. 3 shows a further modification of the embodiment of FIG. 1, wherein the same modification can also be made to the embodiment of FIG. 2. The embodiment of FIG. 3 differs from those of FIGS. 1 and 2 in the following features.

The SiC electrode 4 (SiC layer 4) of the composition and thickness indicated above here is one that is applied to a conductive substrate 36 made of graphite or metal, which is arranged between the SiC electrode 4 on the one hand and the aqueous electrolyte 10 and the nickel foam 6 on the other hand. The window 2 here does not have a thick transparent glass or plastic plate but a thin transparent layer 33 made of a highly transparent plastic, e.g. a resin, Plexiglas or similar, which seals the SiC electrode 4 against dust, impurities etc. Such highly transparent plastics have a significantly higher transmission than glass in the spectral range in which the SiC electrode 4 is photo sensitive, particularly in the UV range.

In this embodiment, the sunlight 5 strikes the SiC layer 4 without being absorbed by any thicker glass or plastic plate. The charge carriers generated therein pass through the conductive substrate 36 and are available for water splitting in the aqueous electrolyte 10 on the side of the substrate 36 opposite the SiC layer 4.

The embodiments have in common that the SiC electrode 4 is designed as a flat surface with two opposing main surfaces, of which one main surface (left in the figures, “dry side” of the photoelectric cell-free of electrolyte) is provided with a window 2, through which sunlight 5 can fall onto the SiC electrode without passing through an aqueous electrolyte, and of which the other main surface (on the right in the figures, “wet side” of the photoelectric cell) is electrically connected over a large area to an aqueous electrolyte 10 and subsequently to the counter electrode (the metal or nickel foam 6). This allows the sunlight 5 to reach the SiC electrode 4 unimpeded by the electrolyte, and the charge carriers generated in the electrode 4 to efficiently cause the photocatalysis of the aqueous electrolyte 10.

The SiC electrode 4 can be an independent thin plate (wafer), which is laminated with the described components to form the photoelectric cell. However, the SiC electrode 4 is advantageously produced as a coating of a substrate, which is the transparent plate 3 serving as the transparent substrate 3, for example made of glass or plastic, or the conductive substrate 36, for example made of graphite or metal.

The method used to coat the substrate 3, 36 should be controllable so that the coating produces an electrode 4 of essentially amorphous SiC or 3C-SiC (preferably nano-or microcrystalline), but not hexagonal SiC. This can be achieved by controlling (limiting) the temperature of the substrate 3, 36 during the coating process.

A suitable coating method is the gas-phase deposition of a 3C-SiC layer 4 or an amorphous SiC layer 4 on the substrate 3, 36 by exposing the substrate 3, 36 to a Si-and C-containing gas. The gas can be generated by heating a Si-and C-containing precursor, for example by heating a solid precursor, for example made from a mixture of fumed silica and carbon black, to temperatures from about 1400° C., preferably about 1600 to 1900° C., or by heating a gaseous precursor, for example comprising a mixture of tetrachlorosilane and a hydrocarbon gas, to temperatures of about 900 to 1300° C. or more. The above-mentioned dopants can be added to the precursor and/or the gas.

During deposition, a temperature gradient should be maintained in which the substrate 3, 36 has a lower temperature than the gas. For the deposition of an amorphous SiC layer 4, the substrate temperatures are in the range of 1100 to 1300° C. For the deposition of a 3C SiC layer 4, the substrate temperatures are in the range from 1400 to 1900° C. For example, the substrate 3, 36 has a temperature of around 1500° C. and the Si-and C-containing gas has a temperature of around 1800° C. in order to deposit 3C-SiC. A deposition process at these temperatures is particularly suitable for coating metal and especially graphite and therefore for coating the conductive substrate 36.

With the following methods, the SiC electrode 4 can be applied at lower temperatures, in particular also at room temperature and therefore particularly gently as a thin layer 4 on the substrate 3, 36, without significantly changing or even damaging it. These methods are therefore suitable not only for coating the conductive substrate 36 but also for coating the transparent substrate 3 made of glass or plastic:
printing the SiC coating 4 on the substrate 3, 36 in the powder bed, which contains a powdery precursor made of fumed silica and carbon black, by means of a laser beam in a 3D printing method at relatively low laser power of, for example, only up to 20 or preferably 10 W for an IR laser or 15 W for a UV laser, wherein an array of several such lasers can also be used in parallel to accelerate the process; or
printing the SiC coating 4 on the substrate 3, 36 in the powder bed containing a powdery precursor made of fumed silica and carbon black, by means of microwave radiation which is excellently absorbed by such a precursor, this method being particularly suitable also for coating a substrate 3 consisting of metal or a metal foil; or
coating the substrate 3, 36 by means of cold plasma spraying by adding said powdery precursor or a liquid suspension of the precursor to a cold plasma jet directed onto the substrate 3, 36; or
flash lamp annealing of a precursor previously applied to the substrate 3, 36, wherein the precursor contains a silicon source and a carbon source in liquid or powder form, for example the aforementioned powdery precursor.

The coating of the transparent plate 3 should not form an opaque layer, for example of excess carbon, which would obstruct sunlight 5, and the coating of the conductive substrate 36 should not form an insulating layer, for example of silicon dioxide, which would obstruct the transport of charge carriers to the nickel foam 6. These requirements can also be achieved with the above-specified temperature gradient and by controlling the composition of the precursor or the Si-and C-containing gas, so that stoichiometric SiC is formed on the substrate 3, 36.

The above-mentioned embodiments can be supplemented and modified. For example, concentrators such as mirrors can be provided in order to focus the sunlight before it enters through the window 2 and to reduce the area required by the photoelectric cell. The window 2 can also simply be an opening in the housing 1 where the SiC electrode 4 is exposed—without the presence of a transparent plate 3. The thin transparent layer 33 also only needs to be present if the SiC electrode 4 is exposed to adverse environmental influences. The photoelectric cell is suitable for operation not only with sunlight but also with light from other sources. The individual features of each embodiment can be combined with the features of another one of the embodiments.

1. A photoelectric cell for the photocatalytic production of hydrogen, comprising:
an electrode (4) containing silicon carbide and having mutually opposite first and second main surfaces,
a window (2) on the side of the first main surface of the electrode (4) for incidence of light (5) from outside the cell onto the electrode (4),
an aqueous electrolyte (10) on the side of the second main surface of the electrode (4), and
a counter electrode (6) in contact with the aqueous electrolyte (10),
wherein the cell on the side of the first main surface of the electrode (4) is electrolyte-free.

2. A photoelectric cell in accordance with claim 1, wherein the electrode (4) is a silicon carbide layer having a thickness in the range of 40 to 80 pm.

3. A photoelectric cell in accordance claim 1, wherein the electrode (4) is a silicon carbide coating of a substrate (3, 36).

4. A photoelectric cell in accordance with claim 3, wherein the window (2) comprises a transparent plate (3) and the substrate is the transparent plate (3).

5. A photoelectric cell in accordance with claim 3, wherein the substrate is a conductive substrate (36) on the second main surface side of the electrode (4).

6. A photoelectric cell in accordance with claim 1, wherein the counter electrode (6) has a metal foam which is soaked with the aqueous electrolyte (10).

7. A photoelectric cell in accordance with claim 6, wherein the metal foam is nickel foam (6).

8. A photoelectric cell in accordance with claim 1, comprising a proton-permeable membrane (7) and an outlet (8) for discharging hydrogen from the cell.

9. A method of manufacturing an electrode (4) for a photoelectric cell according to claim 1, wherein a substrate (3, 36) is exposed to a silicon-and carbon-containing gas while the substrate is maintained at a lower temperature than the gas to deposit a layer (4) of silicon carbide on the substrate (3, 36).

10. An electrode (4), manufactured by the method of claim 9.
